(19) United States
(12) Patent Application Publication
(10) Pub. No.: US 2001/0036594 A1
(43) Pub. Date: Nov. 1, 2001

(54) Resist composition for use in chemical amplification and method for forming a resist pattern thereof

(75) Inventors: Miwa Kozawa, Kawasaki (JP); Koji Nozaki, Kawasaki (JP); Keiji Watanabe, Kawasaki (JP); Ei Yano, Kawasaki (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(73) Assignee: Fujitsu Limited, Kawaswki (JP)

(21) Appl. No.: 09/785,306

(22) Filed: Feb. 20, 2001

(30) Foreign Application Priority Data
Mar. 28, 2000 (JP) 2000-089790

(51) Int. Cl. G03F 7/038; G03F 7/075; G03F 7/004; G03F 7/11; G03F 7/36; G03F 7/30; G03F 7/40

(52) U.S. Cl. 430/270.1; 430/325; 430/326; 430/313; 430/311; 430/271.1

(57) ABSTRACT

Disclosed is a negative resist composition comprising an alkaline-soluble resin and a compound having an oxetane structure. This composition further comprises an acid generator and provides a fine resist pattern with high sensitivity at a wavelength of less than 200 nm. The resist composition can be used in both monolayer and bilayer resist methods, thereby meeting the requirements for high sensitivity at a shorter wavelength and etching resistance.

### CROSS-REFERENCE TO RELATED APPLICATION

This application is based upon and claims priority of Japanese Patent Application No. 2000-89790, filed in Mar. 28. 2000, the content being incorporated herein by reference.

### BACKGROUND OF THE INVENTION

1. Field of the Invention

The present invention generally relates to a novel resist composition, more particularly, to the resist composition for use in chemical amplification with which a fine resist pattern can be formed by developing with an alkaline developer, the pattern being a strong resistant against oxygen plasma etching suitable for manufacture of a semiconductor device. The present invention also relates to a method for forming the pattern using the resist composition.

2. Description of the Related Art

With a high integration of a semiconductor device, a line size and structure of the wiring become increasingly fine and multilayer, respectively. In response to this, it becomes severe for the requirement of a resist material used in a lithographic process. In addition to resolution, attention has been paid to a dimensional accuracy after etching as an important property. Since shifting to a shorter wavelength of an exposing source makes it impossible to keep a sufficient transparency of the resist layer by itself, the resist layer is likely to have thinner layer. As a result, it becomes clear that an etching property of the resist layer has a key factor for manufacture of the semiconductor device. In addition to the semiconductor manufacture, since a lithographic technology has been also employed for a high integration of a photomask necessary for a fine fabrication of the wiring, and manufacture of a magneto-resistance effect head for a high density, the requirement for the resist material has the same problems as the semiconductor manufacture.

As an effective technology, it is suggested the surface imaging be used for the above problems. In particularly, an attempt is made to use a bilayer resist method using a resist composition containing a resin having a silicon atom. The bilayer method comprises forming an lower resist layer by coating a solution containing an organic resin so that the thickness may be 0.5 μm, and forming an upper resist layer having the thickness of about 0.1 μm on the lower resist layer. Then, the bilayer method further comprises exposing the upper resist layer, developing the upper layer to form a upper resist pattern, and etching the lower resist layer by use of the mask of the upper resist pattern, so as to form a resist pattern having a high aspect ratio. As the desired performance of the resist material for use in the bilayer method, it is strongly necessary to meet the requirement for resolution, store stability and alkaline developability which is recently required for a monolayer resist, in addition to resistance to oxygen reactive etching (hereinafter referred to as O₂-RIE). At the present stage, however, there does not exist the resist material which meet all of the above requirement. in chemical amplification with which a fine resist pattern can be formed by developing with a alkaline developer, the pattern being a strong resistant against oxygen plasma etching and a high exposure sensitivity can be attained.

It is another object of the present invention to provide a method for forming a resist pattern using such resist composition.

The above objects of the present invention are achieved by a negative-working resist composition comprising: an alkaline-soluble resin; and a compound having an oxetane structure represented by the following formula.

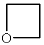

The above objects of the present invention are also achieved by a method for forming a resist pattern comprising the steps of: forming a resist layer on a substrate, the resist layer comprising a resist composition comprising: an alkaline-soluble resin; and a compound having an oxetane structure represented by the following formula:

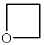

exposing the resist layer to light; baking the resist layer according to need; and developing the resist layer to form the resist pattern.

An advantage of the present invention is that formation of a fine resist pattern can be carried out with high O₂-RIE resistance.

In a further advantage of the present invention, there is provided a resist composition which can be used in both monolayer resist and resist layer to form the resist pattern.

An advantage of the present invention is that formation of a fine resist pattern can be carried out with high 0₂-RIE resistance.

In a further advantage of the present invention, there is provided a resist composition which can be used in both monolayer resist and bilayer resist methods, thereby meeting the requirements for high sensitivity at a shorter wavelength used in microfabrication of the wiring of the semiconductor device, and etching resistance.

Another advantage of the present invention is that high integration of the semiconductor device can be realized by a producing method by use of a resist composition comprising an alkaline-soluble resin and a compound having an oxetane structure.

### BRIEF DESCRIPTION OF THE DRAWINGS

Other objects, features and advantages of the present invention will becomes more apparent from the following detailed description when read in conjunction with the accompanying drawings, in which:

FIG. 1 shows a result of O2-RIE resistance in a bilayer resist by use of a resist composition according to the present invention; and

FIG. 2A through 2C show steps of a method for forming a wiring pattern using the resist composition according to the present invention.

### DESCRIPTION OF THE PREFERRED EMBODIMENTS

As for a compound having an oxetane structure, Japanese Patent Application No. 6-16804 discloses an oxetane compound as a light-cured type coating agent. In contrast to this, the present invention is directed to a resist composition comprising the oxetane compound and a resin which is alkaline-soluble and which shows excellent dry-etching resistance, thereby providing the resist composition for microfabrication lithography.

The oxetane compounds reacts with a alkaline group such as a hydroxyl, carboxyl or the like, by ring-opening reaction of oxetane under certain conditions. Namely, in the presence of an alkaline-soluble resin, the resin can serve as a crosslinking agent and increase in a molecular weight of the resin results in insolubilization thereof. In view of this, the present inventors have considered a composition comprising the oxetane compound and the alkaline-soluble resin to be negative. The oxetane further undergoes cationic polymerization under certain conditions. When the compound having the oxetane structure exhibits alkaline solubility, alkaline solubility is destroyed by cationic polymerization, thereby making an exposed area insoluble. In light of this, the present inventors have considered the composition comprising the compound having the oxetane structure to be negative.

As to the resist composition according to the present invention, a structure of the alkaline-soluble resin is not particularly restricted if the alkaline-soluble resin has an alkaline-soluble group. As a base resin for a monolayer resist composition, use can be made of a phenolic resin, acrylic resin, a copolymer thereof, a silicon atom-containing resin having carboxylic acid, a phenolic hydroxyl group and a hexafluorocarbinol. It is favorable to use the silicon atom-containing resin represented by the following formulae (1) and (2).

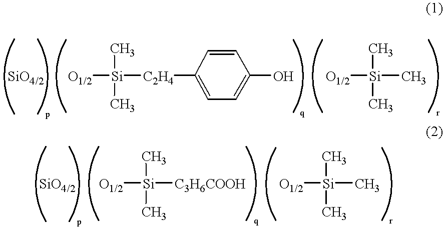

A structure of the oxetane compound is not particularly limited in the present invention. It should be noted that two or more alkalaine-soluble resins can simultaneously exist with two or more oxetane compounds if the resin and the compound meet the above requirements.

The resist composition according to the present invention comprises as a main component the alkaline-soluble resin and as a crosslinking agent the compound having the oxetane structure. The resist composition according to the present invention further comprises an acid generator, thereby providing a negative resist composition based on chemical amplification. Examples of such acid generator may include, but not limited to, an onium salt such as diphenyliodonium salt, triphenylsulfonium salt or the like, ester of sulfonic acid such as benzyl tosylate, benzylsulfonate or the like, a halogenated organic compound such as dibromobisphenol A, trisdibromopropyl isocyanurate or the like. An amount of the acid is preferably present in a range of from 1 to 20 parts by weight relative to 100 parts by weight of the alkaline-soluble resin as the main component of the resist composition. A sufficient sensitivity as the resist can not be obtained when the amount is less than the lower limit. Conversely, degradation of resolution and coating capability occurs when the amount is more than the upper limit. It should be noted that an amount of the compound having the oxetane structure as the crosslinking agent is not particularly limited.

In the case where a resist pattern is formed using the resist composition according to the present invention, use can be made of a method for forming a resist layer directly on a substrate. Alternatively, use can be made of a method for forming a resist pattern, the method comprising forming a first resist layer (a lower resist layer), and then forming a second resist layer (an upper resist layer) on the first layer by use of the resist composition according to the present invention. The method further comprises exposing the upper resist layer to light, developing the upper resist layer to form a patterned upper layer, and etching the lower layer using the patterned upper layer as the mask.

As a resist composition for the lower resist layer, it is possible to use a conventional organic material. It is preferred to use a commercially available resist material such as a novolak resin, a poly(vinyl phenol) resin, and a conductive material based on polyaniline and polythiophene. A thickness of the lower resist layer is preferably between 0.1 and 10 μm, more preferably between 0.2 and 1.0 μm.

In the event of coating the resist composition according to the present invention, use may be made of solvent, if necessary. It is possible to use organic solvents. Examples of such solvent include propyleneglycol monomethylether acetate, n-butyl ether, methyl isobutylketone or the like. As a coating method of the resist composition according to the present invention, use can made of a conventional coating method such as spin coating method or the like. A coated thickness of the resist composition is preferably between 0.03 and 1.0 μm, more preferably between 0.05 and 0.2 μm. A dimensional variation increases during etching step when the thickness is less than the lower limit. Conversely, resolution degradation occurs when the thickness is more than the upper limit.

As a radiation source for exposure, use can made of a visible light, an ultraviolet light, a KrF excimer laser, an ArF excimer laser, a F2 excimer laser or the like, VUV, EUV, an electron ray, ion beam or the like.

When the resist layer is developed, it is possible to use an alkaline developing solution such as tetramehtylammonium hydroxide (TMAH) solution, potassium hydroxide solution or the like.

When the lower resist layer is etched, plasma etching can be performed with an oxygen gas. More particularly, an etching gas preferably comprises oxygen and sulfur oxide. As an plasma etching apparatus, it is possible to use a high density plasma etching apparatus.

### EMBODIMENT

The present invention will be described in greater detail with reference to examples given below, but are not to be construed as limiting the invention.

### Preparative Example

A description will be given of synthesis of a resin represented by the formula (1).

To a four-neck flask provided with a condenser and a thermometer 6.9 g (0.023 mole) of 1,3-bis(carboxypropyl)tetramethyldisiloxane, 35 ml of a purified water and 20.6 ml of acetic acid were added under nitrogen atmosphere. The reaction mixture was stirred and raised to a temperature of 60° C. in an oil bath. 12.48 g (0.06 mole) of tetraethoxysilane was added to the mixture dropwise for 30 minutes and the mixture was reacted for one hour. 6.24 g (0.03 mole) of tetraethoxysilane was then added to the mixture for 30 minutes and the mixture was reacted for 3 hours. After the reaction mixture was cooled to room temperature, the reaction solution was transferred to a separatory funnel. 100 ml of water and 100 ml of methyl isobutylketone (MIBK) were added to the separatory funnel and the solvent was extracted. An organic layer was filtrated with a liquid layer separating filter paper and was transfer the four-neck flask. Water was removed by azeotropic distillation to yield a MIBK solution containing a four-functional siloxane resin.

Next, to the four-neck flask equipped with the condenser and the thermometer, a half-concentrated MIBK solution and 100 ml of tetrahydrofuran was added and 12.0 g (0.84 mole) of trimethylsilylimidazole was then added while stirring at room temperature. The mixture was reacted for two hours. 18 ml of hydrochloric acid was added to the mixture and the reaction mixture was filtrated with the liquid layer separating filter paper and was transfer the four-neck flask. Water was removed by azeotropic distillation. Freeze drying was carried out with hexane to give a silicon atom-containing resin having a molecular weight of 60000 with a yield of 85%. This resin was used in Examples given below.

### EXAMPLE 1

100 parts by weight of the alkaline-soluble silicon atom-containing resin thus synthesized above, 100 parts by weight of silicon atom-containing resin having the molecular weight of 3000 and the oxetane structure represented by the following formula (3)(which was synthesized by a synthesizing method disclosed in Japanese Patent Application No. 6-16804) and 5 parts by weight of triphenylsulfonium triflate were dissolved in propyleneglycol monomethylether acetate (PGMA) so as to prepare a resist solution.

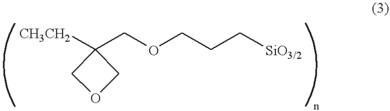

The resist solution was spin-coated on a S1 substrate which was pre-subjected to hexamethyldisilazane treatment and prebaking was performed at 100° C. for 60 seconds to form a resist film having the thickness of 0.14 μm. After exposing the resist film by means of the KrF excimer laser stepper (NA=0.45), baking was carried out at 135° C. for 60 seconds. Development of the resist film with 2.38% of TMAH resulted in formation of a line and space of 0.25 μm with an exposure amount of 7 mJ/cm².

### EXAMPLE 2

100 parts by weight of the alkaline-soluble silicon atom-containing resin having the molecular weight of 6000 and the formula (1), 70 parts by weight of silicon atom-containing resin having the molecular weight of 3000 and the oxetane structure represented by the following formula (3) and 3 parts by weight of triphenylsulfonium triflate were dissolved in MIBK so as to prepare a resist solution.

First of all, a solution based on a novolak resin was spin-coated on the Si substrate and baking was carried out in an oven at 280° C. for 3 hours to form the lower resist layer having the thickness of 0.4 μm. The resist solution thus prepared above was then spin-coated on the lower resist layer and prebaking was performed at 110° C. for 60 seconds to form the upper resist layer having the thickness of 0.1 μm. Exposure of the upper resist layer by means of the ArF excimer laser exposing apparatus resulted in formation of a latent upper resist pattern. Baking was carried out at 140° C. for 60 seconds. Development of the resist film with 2.38% of TMAH resulted in formation of a line and space of 0.17 μm with an exposure amount of 10 mJ/cm².

### EXAMPLE 3

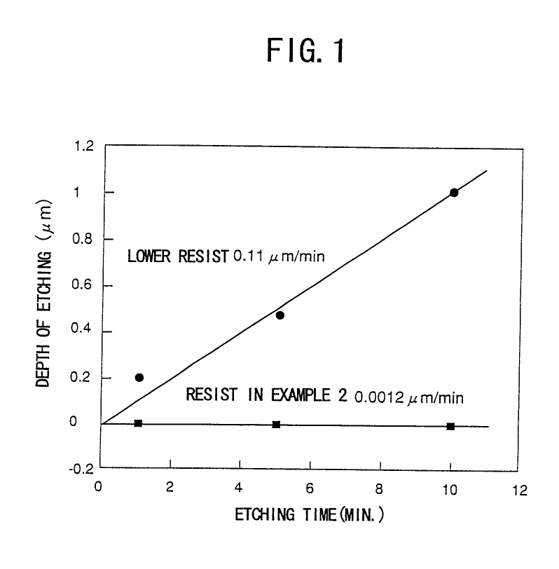

The upper pattern was transferred to the lower resist layer by means of O₂ - RIE using the upper resist pattern formed in Example 2 as the mask. The conditions of O₂-RIE is as follows: RF power; 0.16 W/cm², oxygen flow; 10 sccm, gas pressure; 10 mTorr. The results of etching rate is shown FIG. 1. Under these conditions O₂-RIE resistance of the upper resist was 100 times that of the lower resist. As a result, it was confirmed that a line and space pattern of 0.17 μm which was formed in the upper resist layer was successfully transferred to the lower resist layer without dimensional variation.

### EXAMPLE 4

100 parts by weight of the alkaline-soluble silicon atom-containing resin having the molecular weight of 6000 and the formula (1), 50 parts by weight of silicon atom-containing resin having the molecular weight of 3000 and the oxetane structure represented by the following formula (3) and 5 parts by weight of triphenylsulfonium triflate were dissolved in MIBK so as to prepare a resist solution.

As with Example 2, the lower resist layer was formed on the Si substrate so that the thickness was 0.4 μm. Subsequently, the resist solution thus prepared above was spin-coated on the lower resist layer and prebaking was carried out at 110° C. for 60 seconds to form the upper resist layer having the thickness of 0.1 μm. Exposure of the upper resist layer by means of the electron ray exposing apparatus resulted in formation of a latent upper resist pattern. Baking was carried out at 135° C. for 60 seconds and development of the resist film with 2.38% of TMAH resulted in formation of a line and space of 0.125 μm with an exposure amount of 45 μC/cm².

### EXAMPLE 5

The upper pattern was transferred to the lower resist layer by means of O₂ - RIE using the upper resist pattern formed in Example 4 as the mask. Under the same conditions as in Example 3 O₂ -RIE resistance of the upper resist was 90 times that of the lower resist. As a result, it was confirmed that a line and space pattern of 0.125 μm which was formed in the upper resist layer was successfully transferred to the lower resist layer without dimensional variation.

### EXAMPLE 6

A more specific method for manufacturing the semiconductor device will be described below using the resist composition according to the present invention.

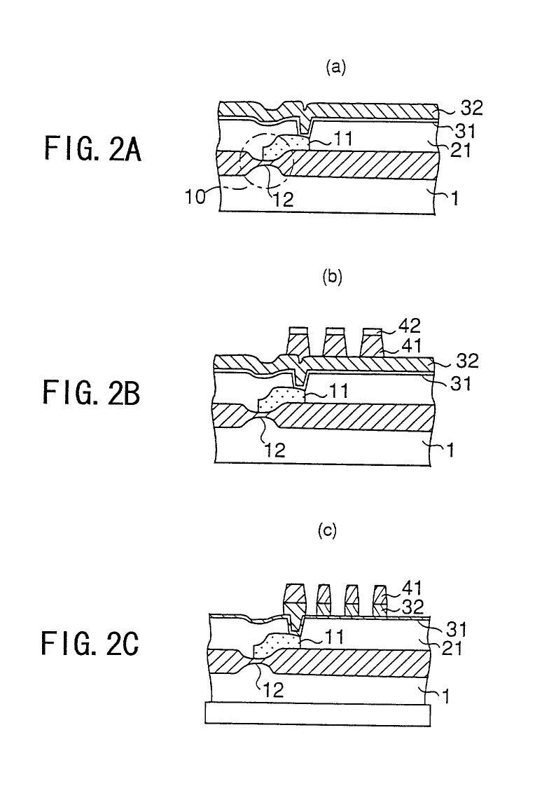

FIGS. 2A-2C show a forming method of a wiring pattern of a gate necessary for a high aspect ratio. An isolated MOS transistor 10 is provided on a silicon substrate 1 by means of field oxidation. An insulating layer 21 is formed on a gate electrode 11 of the MOS transistor and an opening is formed by means of a lithographic means in order to draw a wiring from the gate electrode 11. As a barrier metal, a thin film 31 of titanium nitride (TiN) is then formed on the insulating layer 21 and a thin film made 32 of Al as a wiring material is deposited on the TiN (See, FIG. 2A).

In order to process this Al/TiN layers as the wiring pattern, a resist pattern 42 is formed thereon as an etching mask according to a procedure described in Example 2. The resist pattern is then transferred to a lower layer by means of an oxygen plasma etching method using resist pattern 42 as the mask (See, FIG. 2B). Then, the resist pattern 42 is then removed by fluorine-based plasma etching to form an etching mask 41.

By use of the etching mask 41, the Al/TiN stacked layer is etched by means of chlorine-based plasma so as to provide a gate wiring pattern having the high aspect ratio of 7 (See, FIG. 2C).

The present invention is not limited to the specifically disclosed embodiments, and variation and modifications may be made without departing from scope of the present invention.

What is claimed is:

1. A negative resist composition comprising:
an alkaline-soluble resin; and
a compound having an oxetane structure represented by the following formula:

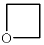

2. The negative resist composition as claimed in claim 1, wherein the alkaline-soluble resin comprises a resin containing a silicon atom.

3. The negative resist composition as claimed in claim 1, wherein the alkaline-soluble resin comprises a resin having a functional group selected from the group consisting of a carboxyl group, a phenolic hydroxyl group and hexafluorocarbinol represented by the following formula.

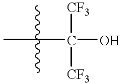

4. The negative resist composition as claimed in claim 2, wherein the resin having the silicon atom contains a carboxyl group.

5. The negative resist composition as claimed in claim 2, wherein the resin having the silicon atom contains a phenolic hydroxyl group.

6. The negative resist composition as claimed in claim 2, wherein the resin having the silicon atom contains a hexafluorocarbinol represented by the following formula.

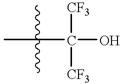

7. The negative resist composition as claimed in claim 1, the compound having the oxetane structure comprises a resin having a silicon atom represented by the following formula.

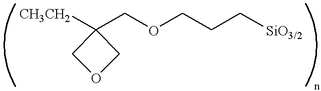

8. The negative resist composition as claimed in claim 1, further comprising an acid generator and the resist composition is used for chemical amplification.

9. The negative resist composition as claimed in claim 1, wherein the resist composition having sensitivity for wavelength range of less than 200 nm.

10. A method for forming a resist pattern comprising the steps of:
forming a resist layer on a substrate, the resist layer comprising a resist composition comprising an alkaline-soluble resin and a compound having an oxetane structure represented by the following formula; 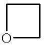
exposing the resist layer to light;
baking the resist layer according to need; and
developing the resist layer to form the resist pattern.

11. A method for forming a resist pattern comprising the steps of:
forming a first resist layer on a substrate, the first resist layer comprising a first resist composition;
forming a second resist layer on the first resist layer, the second resist layer comprising a resist composition comprising an alkaline-soluble resin and a compound having an oxetane structure represented by the following formula; 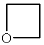
exposing the second resist layer to light;
post-exposure baking the second resist layer
developing the second resist to form a desired pattern; and
etching the first resist layer by use of the second layer as a mask.

12. A method for manufacturing a semiconductor device comprising the step of forming method as claimed in claim 10 or 11.
